(19) United States
(12) Patent Application Publication
(10) Pub. No.: US 2020/0340437 A1
(43) Pub. Date: Oct. 29, 2020

(54) HIGH PRESSURE HYDRAULIC SYSTEM COMPRISING A SENSOR FOR NON-INVASIVE DIAGNOSTICS

(71) Applicant: OMT DIGITAL S.r.l., Torino (IT)

(72) Inventors: Marco COPPO, Torino (IT); Francesco CATUCCI, Putignano (Bari) (IT); Lorenzo CHIARBONELLO, Buttigliera Alta (Torino) (IT); Andrea VIOLINO, San Gillio (Torino) (IT)

(21) Appl. No.: 16/858,799

(22) Filed: Apr. 27, 2020

(30) Foreign Application Priority Data
Apr. 29, 2019 (IT) 102019000006429

(51) Int. Cl. F02M 57/00; G01L 9/00; H01L 41/113

(52) U.S. Cl. CPC F02M 57/005; F02M 2200/247; H01L 41/1132; G01L 9/008

(57) ABSTRACT

A high pressure hydraulic system comprising: a hydraulic chamber containing pressurized fluid, a wall which encloses at least one part of the hydraulic chamber and has an integral diaphragm, a piezoelectric sensor isolated from the pressurized fluid contained in the hydraulic chamber by the diaphragm, and an elastic element arranged to apply an elastic force to the piezoelectric sensor, between the piezoelectric sensor and the diaphragm, so that a deformation of the diaphragm produced by a change in the pressure of the fluid contained in the hydraulic chamber causes a change in the elastic force that the elastic element applies to the piezoelectric sensor.

### FIELD OF THE INVENTION

The present invention relates in general to high pressure hydraulic systems and regards a high-pressure hydraulic system comprising a sensor for non-invasive diagnostics of the operation of the system.

The invention was developed in particular in view of its application to the diagnostics of fuel injection systems for large diesel and dual-fuel engines, for example, for large naval engines. In the following description, reference will be made to this specific field of use without, however, losing generality.

### DESCRIPTION OF THE PRIOR ART

In the field of hydraulic systems, and in particular of high pressure injection systems for Diesel engines, there is a growing interest in the development of diagnostic systems capable of acquiring significant data for the diagnostics of operation of complex systems.

This has prompted the development of low-cost sensors that are able to measure characteristic operating parameters, such as hydraulic pressure.

In the field of fuel injection systems, sensors have been proposed for measuring the force and/or pressure and, in particular, configured for being fixed to a fuel injector for identifying the closing time of the injector needle. For example, EP3001167 describes a sensor assembly comprising at least one sensor element of piezoelectric material with two end faces located parallel to each other and each with an associated electrode, wherein the electrodes, which are electrically insulated from each other, are envisaged to be in contact with the sensor element.

Hydraulic systems have also been proposed in which the sensors are integrated into the components to be monitored (e.g. EP3026254 and EP3034855).

In common-rail fuel injectors, the sensors are often placed in areas adjacent to the hole that carries the fluid from the pressurized accumulator towards a fuel dispensing chamber located upstream of the injector needle sealing area. This allows detection of operating data of the injector, but not of its control valve, since the perturbations it generates during operation do not propagate up to this line.

The ideal position for a pressure sensor for diagnostic purposes would be close to the injector control chamber. However, due to the small size of this area and the high pressures of the fluid present in the control chamber, it would be necessary to use small sensor elements, which are therefore limited in terms of the loads and deformations they can withstand. In general, the problem is that it is necessary to manage deformations generated by very high pressures (in the order of thousands of bars) in small spaces.

US2014027534A1 describes a fuel injector for a common-rail injection system, comprising a piezoelectric pressure sensor to detect pressure variations during the opening and closing of the injection needle, in order to determine the moment of closure of the injector needle. The pressure sensor is arranged in a low pressure region, and is loaded by an axial force produced by the rod of a control valve. The sensor described in US2014027534A1 has the object of detecting the pressure in a chamber located downstream of the control chamber and connected thereto by means of a calibrated orifice. Therefore, the sensor described in this document is unable to directly detect a signal representative of the pressure in the control chamber. In fact, when the valve is open, the pressure read by the sensor is at an intermediate level between the pressure in the control chamber and the discharge pressure, and this level is also determined by the pressure drop across the valve seat. When the valve is closed, the orifice-intermediate chamber system introduces a delay between the pressure signal in the control chamber and the pressure signal detected by the sensor.

### OBJECT AND SUMMARY OF THE INVENTION

The object of the present invention is to provide a high pressure hydraulic system that detects a signal related to the pressure of the fluid inside the hydraulic system, in a cost-effective and non-invasive way.

According to the present invention, this object is achieved by a high pressure hydraulic system having the characteristics forming the subject of claim 1.

The characterizing element of the present invention is the particular arrangement and conformation of sensitive and supporting elements that make up the sensor and that make it possible to integrate it into different hydraulic systems. The electrical signal provided by this sensor can be used to diagnose the operation of the hydraulic system through classic techniques or by means of artificial intelligence.

In particular, in the case of applications in injection systems, the small size, the resistance to high temperatures, and the adaptability to integration in components having different rigidities, make the sensor suitable for detecting the pressure in the control volume of common-rail injectors, from which it is possible to derive a series of operating diagnosis parameters for the entire injector.

The claims form an integral part of the disclosure provided here in relation to the invention.

### BRIEF DESCRIPTION OF THE DRAWINGS

The present invention will now be described in detail with reference to the attached drawings, given purely by way of non-limiting example, wherein:

FIG. 1 is a partial cross-section of an injector for common-rail injection systems,

FIG. 2 is a cross-section on an enlarged scale of the part indicated by the arrow II in FIG. 1,

FIG. 3 is a cross-section along the line III-III of FIG. 2, and

FIG. 4 is a cross-section along the line IV-IV of FIG. 3.

### DETAILED DESCRIPTION

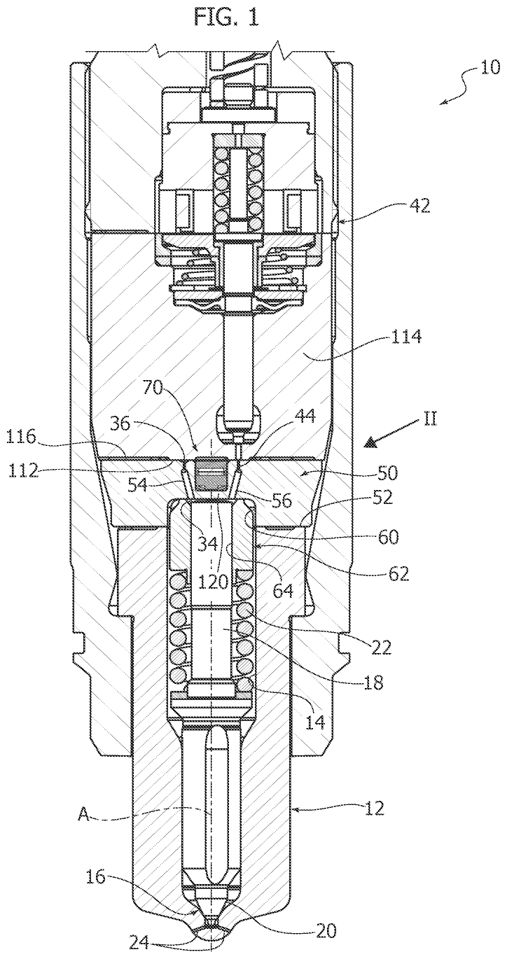

FIG. 1 illustrates a high pressure hydraulic system. In the example illustrated, the hydraulic system consists of an injector 10 for a common-rail injection system. The injector 10 comprises a pulverizer 12 having a fuel dispensing chamber 14 having a valve seat 16. An injector needle 18 extends into the dispensing chamber 14, and has a sealing surface 20 which cooperates with the valve seat 16. The injector needle 18 is movable along its longitudinal axis A between a closed position in which the sealing surface 20 abuts against the valve seat 16, and an open position in which the sealing surface 20 is spaced apart from the valve seat 16. A spring 22 tends to push the injector needle 18 towards the closed position. The pulverizer 12 has a plurality of injection holes 24 through which the pressurized fuel located in the dispensing chamber 14 is pulverized when the injector needle 18 is in the open position.

The dispensing chamber 14 is connected to an accumulation volume filled with pressurized fuel coming from a high-pressure pump. The accumulation volume is also connected to a hydraulic chamber 34 via a hydraulic line on which a first calibrated orifice 36 is arranged. The hydraulic chamber 34 is connected to a discharge line which leads to a tank. A control valve 42 is arranged on the discharge line. The control valve 42 is an electrically-controlled two-position valve which—in the open position—connects the hydraulic chamber 34 to the discharge line, and—in the closed position—isolates the hydraulic chamber 34 from the discharge line. A second calibrated orifice 44 is arranged upstream of the control valve 42.

The injector 10 comprises a wall 50 arranged in hydraulic sealing contact with a head surface 52 of the pulverizer 12. The wall 50 encloses at least one part of the hydraulic chamber 34. In the wall 50, the calibrated orifices 36, 44 are formed, which are connected to the hydraulic chamber 34 through respective holes 54, 56 which are also formed in the wall 50.

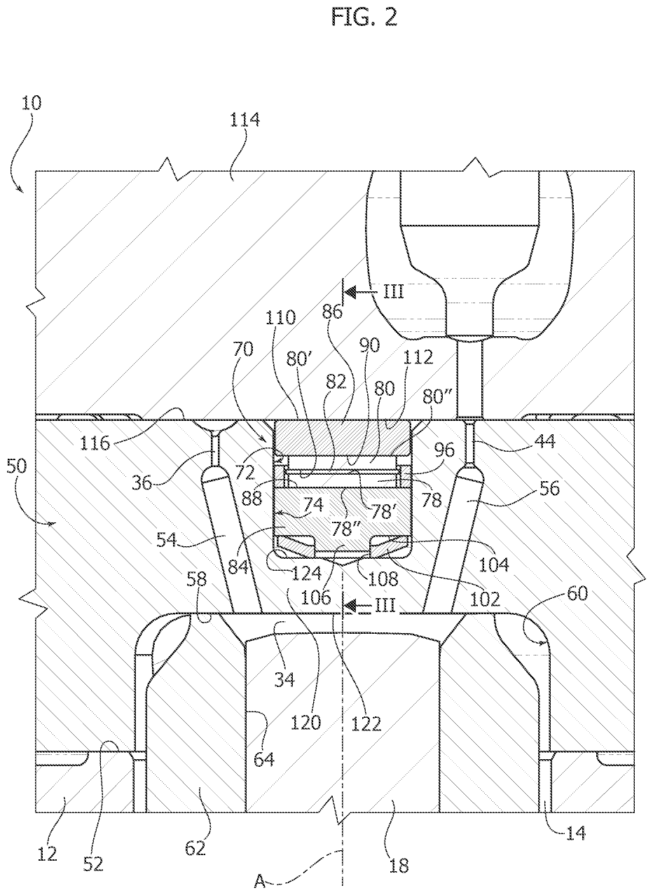

With reference to FIG. 2, the wall 50 has a reaction surface 58 against which the pressure of the fluid contained in the hydraulic chamber 34 acts. The holes 54, 56 are open on a part of the reaction surface 58 facing the hydraulic chamber 34. In some embodiments, the hole 54 and the orifice 36 can be exchanged with respect to the arrangement illustrated in FIG. 2.

The reaction surface 58 of the wall 50 can be formed in a seat 60 of the wall 50 open towards the dispensing chamber 14 of the pulverizer 12. A bushing 62 is partially housed inside the seat 60 and has a hole 64 in which a head portion of the injector needle 18 slides.

The hydraulic chamber 34 is delimited by the reaction surface 58 of the wall 50, by a head surface 66 of the injector needle 18 and by an annular portion 68 of the guide bushing 62.

With reference to FIGS. 2, 3 and 4, the injector 10 comprises a piezoelectric sensor 70 which provides an electrical signal indicative of the operation of the injector 10.

The sensor 70 is completely isolated from the pressurized fluid contained in the hydraulic chamber 34. The electrical signal provided by the sensor 70 is indicative of the deformations of the wall 50 generated by the changes in fluid pressure in the hydraulic chamber 34. The piezoelectric sensor 70 is a pressure transducer that provides an electrical signal related to the pressure of the fluid in the hydraulic chamber 34. The sensor 70 has a detection axis A that constitutes the direction along which the sensor 70 is capable of detecting pressure variations. The detection axis A may coincide with the longitudinal axis of the injector 10.

The wall 50 comprises an integral diaphragm 120 formed by a portion with reduced thickness of the wall 50. The diaphragm 120 has a first surface 122 in direct contact with the pressurized fluid contained in the hydraulic chamber 34, and a second surface 124, opposite the first surface 122, which is not in contact with the pressurized fluid contained in the hydraulic chamber 34. The first surface 122 of the diaphragm 120 consists of a portion of the reaction surface 58.

In the illustrated embodiment, the diaphragm 120 is located at the bottom of a blind hole 72 in which the sensor 70 is housed. The blind hole 72 is formed in the wall 50 and has a side surface 74 coaxial with the detection axis A of the sensor 70, and a bottom surface forming the second surface 124 of the diaphragm 120.

The sensor 70 comprises two disc-shaped elements 78, 80. The two disc-shaped elements 78, 80 have respective first faces 78′, 80′ and respective second faces 78″, 80″. The first and second faces 78′, 80′ and 78″, 80″ of each of the two disc-shaped elements are plane faces parallel to each other and perpendicular to the detection axis A, which can have a circular shape in a plane perpendicular to the axis A (FIG. 4).

At least one of the two disc-shaped elements is a piezoelectric element that—when subjected to a compression load in the direction of the detection axis A—generates an accumulation of positive charges on the first face 78′, 80′ and negative charges on the second face 78″, 80″. The amount of electric charges generates a potential difference between the faces 78′, 80′ and/or 78″, 80″ which increases proportionally to the pressure increase in the direction of the detection axis A.

In one embodiment, both disc-shaped elements 78, 80 are piezoelectric elements. In this case, the first faces 78′, 80′ of the disc-shaped elements 78, 80 are positive terminal faces and the second faces 78″, 80″ of the disc-shaped elements 78, 80 are negative terminal faces.

In a possible variant, only one of the two disc-shaped elements 78, 80 is a piezoelectric element, and the other of the two disc-shaped elements 78, 80 can be an insulating element without piezoelectric properties.

An electrode 82 formed by a thin wall of conductive material is arranged between the two disc-shaped elements 78, 80, said electrode 82 is perpendicular to the detection axis A. The first faces 78′, 80′ of the two disc-shaped elements 78, 80 are in contact with opposite faces of the electrode 82. The electrode 82 may have a circular shape with a diameter slightly larger than the diameter of the piezoelectric elements 78, 80.

The sensor 70 may comprise two supporting elements 84, 86 of electrically-conductive material. The two supporting elements 84, 86 have respective supporting faces 88, 90 resting against respective second faces 78″, 80″ of the disc-shaped elements 78, 80. The side walls of the supporting elements 84, 86 can be in contact with the side surface 74 of the hole 72.

The electrode 82 arranged between the two piezoelectric elements 78, 80 constitutes the positive pole of the sensor 70. The negative pole consists of the supports 84, 86 electrically-connected to ground through the wall 50.

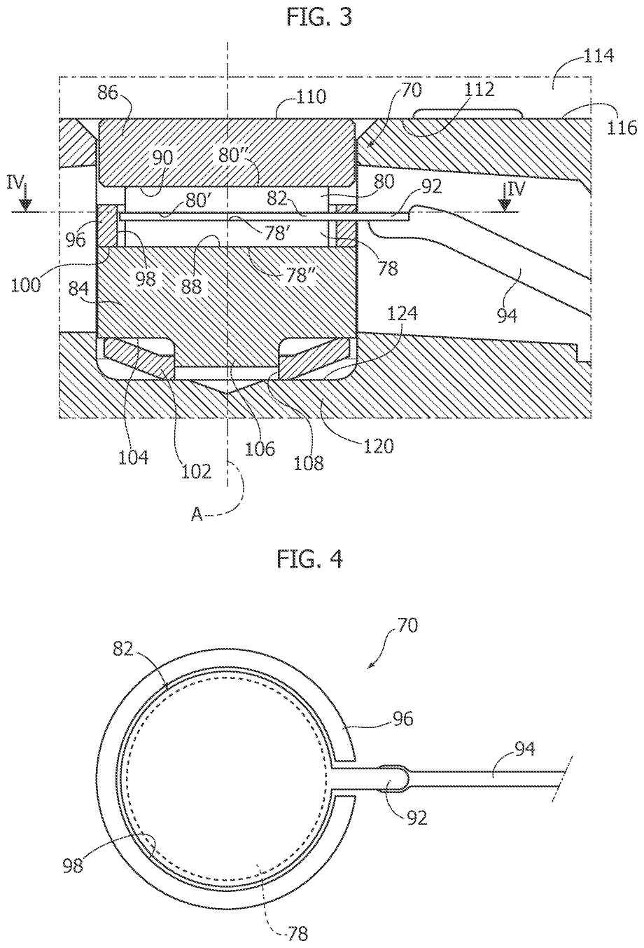

With reference to FIGS. 3 and 4, the electrode 82 may have a protruding portion 92 which extends outwards in a direction perpendicular to the detection axis A, to which one end of an electric cable 94 is connected, on which an analog electrical signal passes whose amplitude is proportional to the force acting between the two supports 84, 86 in the direction of the detection axis A.

The sensor 70 comprises an insulating element 96 with an annular shape, arranged coaxially with the axis A outside the electrode 82. The insulating element 96 has an inner surface 98 facing the outer edges of the disc-shaped elements 78, 80 and of the electrode 82, and which allows the centering between the disc-shaped elements 78, 80 and the electrode 82 with respect to the detection axis A. The insulating element 96 guarantees electrical insulation of the electrode 82 and of the disc-shaped elements 78, 80 from the metal components of the injector. The insulating element 96 has a dimension in the direction of the detection axis A that is less than the distance between the supporting faces 88, 90 of the supporting elements 84, 86, and has a base surface 100 that rests on the outer perimeter part of the face 88 of one supporting element 84.

The sensor 70 is constrained to the wall 50 in the direction of the detection axis A. For example, an upper surface 110 of the supporting element 86 of the sensor 70 can be arranged in abutment against a lower surface 112 of a body 114 which rests against an upper surface 116 of the wall 50.

The injector 10 may comprise at least one elastic element 102, formed, for example, by a cup spring, coaxial with the detection axis A and arranged to apply an elastic force in the direction of the detection axis A between the sensor 70 and the diaphragm 120. The elastic element 102 and the sensor 70 are arranged so that in the direction of the detection axis A the sensor 70 is only subject to the elastic force produced by the elastic element 102.

In the example illustrated, the elastic element 102 is axially compressed between the second surface 124 of the diaphragm 120 and a lower surface 104 of the supporting element 84. The supporting element 84 may have an axial protrusion 106 protruding from the lower surface 104 in the direction of the detection axis A, and which engages a central hole 108 of the elastic element 102. The elastic element 102 compresses the sensor 70 in the direction of the detection axis A against the lower surface 112 of the body 114.

The sensor 70 generates an electrical signal related to the elastic force that the elastic element 102 applies along said detection axis A between the piezoelectric sensor 70 and the diaphragm 120. During operation, the cyclic pressure variations of the fluid in the hydraulic chamber 34 cause cyclic deformations of the diaphragm 120 in the direction of the detection axis A. The deformations of the diaphragm 120 caused by the variations in pressure of the fluid cause deformations in the direction of the detection axis A of the second surface 124 of the diaphragm 120. The deformations of the second surface 124 in the direction of the detection axis A—in turn—cause variations in the elastic force that the elastic element 102 applies to the sensor 70 and, therefore, a variation of the electrical signal generated by the sensor 70. The electrical signal generated by the sensor 70 is, therefore, directly related to the instantaneous value of the pressure of the fluid contained in the hydraulic chamber 34.

The forces due to the deformation of the diaphragm 120 are transmitted to the sensor only by means of the elastic element 102 and this prevents deformation of the diaphragm 120 (under the action of the pressure in the hydraulic chamber 34) generating excessive loads on the sensor 70.

The rigidity of the elastic element 102 is sized according to the thickness of the diaphragm 120 and the pressure in the hydraulic chamber 34. By means of an appropriate choice of the dimensions and geometry of the elastic element 102, the rigidity of the elastic element 102 can be adapted so that the deformation of the diaphragm 120 generates a force compatible with the working range of the piezoelectric elements 78, 80.

The possibility of varying the rigidity of the elastic element 102 at the design stage allows an adequate thickness of the diaphragm 120 to be guaranteed.

In the case in which both disc-shaped elements 78, are piezoelectric elements, the facing and opposite arrangement of the piezoelectric elements 78, 80 doubles the sensitivity of the sensor 70 with respect to a sensor that uses a single piezoelectric element, and simplifies its construction since it uses the same piezoelectric elements 78, 80 as electrical insulation elements between the positive pole and the negative pole and avoids the introduction of further elements of insulating material into the stack of elements that support the load to which the sensor 70 is subject.

The sensor 70 has very small dimensions and can be easily housed between the calibrated orifices 36, 44 of the wall 50. The sensor 70 is capable of providing an indirect measurement of the hydraulic pressure in the hydraulic chamber 34 without any contact with the fluid and without modifying the geometry of the hydraulic chamber 34 in any way. The deformations of the diaphragm 120 can be detected by the sensor 70 with an excellent signal/noise ratio.

The hydraulic pressure inside the hydraulic chamber 34 detected by the sensor 70 can be processed to obtain diagnostic information on the operation of the injector 10.

The drawings illustrate, by way of example, application of the sensor 70 according to the present invention in a common-rail injector. However, it is understood that the sensor 70 according to the present invention can be used in high pressure hydraulic systems of any other type, such as, for example, accumulators, pipes, pumps, valve elements, etc.

In general, the sensor 70 can be mounted in any component of a hydraulic system having a surface exposed to a pressurized fluid, and which deforms due to changes in the pressure of the fluid.

The sensor 70 is, therefore, able to detect the pressure of the fluid without direct contact with the pressurized fluid, thanks to the deformations of the diaphragm that separates the sensor 70 from the volume containing the pressurized fluid.

The elastic element 102 could be arranged differently from that illustrated in the drawings, provided that the sensor 70 in the direction of the detection axis A is only subject to the action of the elastic force produced by the elastic element 102. For example, the elastic element could be arranged between the surface 112 of the body 114 and the upper surface 110 of the second supporting element 84.

Of course, without prejudice to the principle of the invention, the details of construction and the embodiments can be widely varied with respect to those described and illustrated, without thereby departing from the scope of the invention as defined by the claims that follow.

1. A high pressure hydraulic system comprising:
a hydraulic chamber containing pressurized fluid,
a wall which encloses at least one part of the hydraulic chamber and comprises an integral diaphragm,
a piezoelectric sensor isolated from the pressurized fluid contained in the hydraulic chamber by said diaphragm and having a detection axis, wherein the piezoelectric sensor generates an electrical signal related to a force that compresses the piezoelectric sensor along the detection axis, and
an elastic element arranged to apply an elastic force along said detection axis between the piezoelectric sensor and the diaphragm, wherein the elastic element and the sensor are arranged so that a deformation of the diaphragm in a direction of the detection axis produced by a variation of pressure of the pressurized fluid contained in the hydraulic chamber causes a variation of the elastic force that the elastic element applies along the detection axis between the piezoelectric sensor and the diaphragm.

2. The hydraulic system according to claim 1, wherein the elastic element and the piezoelectric sensor are arranged so that in the direction of the detection axis the piezoelectric sensor is only subject to the elastic force produced by the elastic element.

3. The hydraulic system according to claim 1, wherein said diaphragm is formed by a portion with reduced thickness of said wall.

4. The hydraulic system according to claim 3, wherein said diaphragm is located at a bottom of a blind hole formed in said wall and in which said piezoelectric sensor is housed.

5. The hydraulic system according to claim 1, wherein said piezoelectric sensor comprises:
two disc-shaped elements having respective first faces and respective second faces parallel to each other and perpendicular to the detection axis, wherein at least one of said disc-shaped elements is a piezoelectric element,
an electrode formed by a thin plate of conductive material, which is perpendicular to the detection axis, wherein the first faces of the two disc-shaped elements are in contact with opposite faces of the electrode, and
two supporting elements of electrically-conductive material with respective supporting faces resting against respective second faces of the disc-shaped elements.

6. The A hydraulic system according to claim 5, wherein said elastic element is compressed in the direction of the detection axis between said diaphragm and one surface of said two supporting elements.

7. The hydraulic system according to claim 5, wherein the piezoelectric sensor comprises an annular-shaped insulating element, arranged coaxially with the detection axis on an outside of the electrode, wherein the insulating element has an inner surface facing outer edges of the two disc-shaped elements and the electrode.

8. The hydraulic system according to claim 7, wherein the insulating element has a dimension in the direction of the detection axis that is less than a distance between the supporting faces of the two supporting elements, and has a base surface that rests on an outer perimeter part of the supporting face of one of the two supporting elements.

9. The hydraulic system according to claim 5, wherein said two disc-shaped elements are piezoelectric elements, and wherein the first faces of the two disc-shaped elements are positive terminal faces and the second faces of the two disc-shaped elements are negative terminal faces.

10. The hydraulic system according to claim 5, wherein one of said two supporting elements has an axial projection that protrudes from its lower surface in the direction of the detection axis and that engages a central hole of the elastic element.
